(19) United States
(12) Patent Application Publication
(10) Pub. No.: US 2012/0034734 A1
(43) Pub. Date: Feb. 9, 2012

(54) SYSTEM AND METHOD FOR FABRICATING THIN-FILM PHOTOVOLTAIC DEVICES

(75) Inventors: Piero Sferlazzo, Marblehead, MA (US); Thomas Michael Lampros, Cambridge, NY (US)

(73) Assignee: AVENTA TECHNOLOGIES LLC, Danvers, MA (US)

(21) Appl. No.: 13/180,693

(22) Filed: Jul. 12, 2011

Related U.S. Application Data
(63) Continuation-in-part of application No. 13/173,100, filed on Jun. 30, 2011.
Application No. 13/173,100 is a continuation-in-part of application No. 13/101,538, filed on May 5, 2011.
Application No. 13/101,538 is a continuation-in-part of application No. 12/850,939, filed on Aug. 5, 2010.

(51) Int. Cl. H01L 31/18

(52) U.S. Cl. 438/95; 257/E31.008

(57) ABSTRACT

Described are embodiments of methods for depositing a copper indium gallium diselenide (CIGS) film on a substrate, such as a web substrate or a discrete substrate. In various embodiments, an incremental layer of indium is deposited followed by deposition of a top incremental layer of copper gallium to create a multi-layer structure that is subsequently selenized. By capping the multi-layer structure with the copper gallium layer, the depletion of indium during the selenization of the multi-layer is reduced or eliminated. Additional multi-layers, each having a copper gallium cap layer, are formed and selenized to create the CIGS film. Optionally, the indium content and gallium content in each multi-layer are varied from the indium content and gallium content of one or more of the other multi-layers to achieve desired content gradients in the CIGS film.

### RELATED APPLICATIONS

This application is a continuation-in-part of U.S. patent application Ser. No. 13/173,100, titled “System and Method for Fabricating Thin-Film Photovoltaic Devices” and filed Jun. 30, 2011, which is a continuation-in-part of U.S. patent application Ser. No. 13/101,538, titled “System and Method for Fabricating Thin-Film Photovoltaic Devices” and filed May 5, 2011, which is a continuation-in-part application of U.S. patent application Ser. No. 12/850,939, titled “System and Method for Fabricating Thin-Film Photovoltaic Devices” and filed Aug. 5, 2010.

### FIELD OF THE INVENTION

The invention relates generally to the manufacture of electronic devices. More particularly, the invention relates to a method and a system for forming photovoltaic light absorbing Chalcopyrite compound layers of copper indium gallium diselenide (CIGS) on substrates for fabrication of thin film solar cells and modules.

### BACKGROUND OF THE INVENTION

Thin film solar cells have attracted significant attention and investment in recent years due to the potential for lowering the manufacturing costs of photovoltaic solar panels. Most solar panels are fabricated from crystalline silicon and polycrystalline silicon. While silicon-based technology enables fabrication of high efficiency solar cells (up to 20% efficiency), material costs are high due the embodied energy to refine and grow the bulk silicon ingots of silicon from silicon dioxide. In addition, sawing these ingots into wafers results in approximately 50% of the material being wasted. These solar cells are the primary component of the majority of solar panels made and sold today. Presently, silicon solar cells are approximately 90 μm thick. In contrast, thin film solar cells include layers that are approximately 1 μm to 3 μm thick and are deposited directly onto low cost substrates. Among the most popular materials used are amorphous silicon, copper indium diselenide and its alloys with gallium or aluminum (CIS, CIGS, CIAS) and cadmium telluride (CdTe).

Typically, amorphous silicon has the lowest manufacturing costs in terms of cost per unit of power produced, but the efficiencies of the solar cells are generally less than 10% which is low relative to the efficiencies of other materials. CIGS and CdTe cells have higher efficiencies and in the lab have achieved efficiencies approaching and sometime exceeding the efficiencies of silicon-based cells. Small area laboratory-scale cells have demonstrated efficiencies in excess of 20% and 18% for CIGS and CdTe, respectively; however, the transition to volume manufacturing and larger substrates is difficult and substantially lower efficiencies are realized.

Recently, CIGS solar cells have been produced in the laboratory and in production using a three phase co-evaporation process. In this process effusion sources of copper (Cu), indium (In) and gallium (Ga) evaporate at the same time in the presence of a selenium source. In this manner, deposition and selenization occur in a single step as long as the substrate temperature is maintained between about 400° C. and 600° C. Typically, higher temperatures result in higher efficiencies; however, not all substrates are compatible with higher temperatures. Sodium is often added to the mixture of sources and has been shown to enhance minority carriers and to improve voltage. Sodium may also passivate surfaces and grain boundaries. The deposition is repeated three times. For each deposition, the relative concentrations of copper, indium and gallium are changed, thus producing a graded compositional structure that can be more effective at absorbing and converting incident light into electrical power.

Scaling the three phase co-evaporation process to production levels is complicated due to a number of fundamental difficulties. First, effusion sources require high power consumption at production scale because the sources need to be maintained at temperatures as high as 1,500° C. At these high temperatures many materials are extremely reactive. Longevity of system components is decreased and process control and maintenance are difficult. Thus costs associated with production systems are high and downtime can be significant.

The substrate temperature is high during the selenization process. Consequently, the selenium residence time on the substrate surface is small and the selenium utilization efficiency is low. Selenium utilization and unwanted accumulation in various regions of the process chamber make the co-evaporation process difficult to manage in a production environment.

A number of groups have fabricated solar cells using the co-evaporation process while other groups have adopted production-compatible alternatives. One common alternative approach is based on a two-step process that typically includes depositing the metals (copper, indium and gallium) on a substantially cold substrate, that is, a substrate near or at ambient temperature. The deposited metals are then selenized in a hydrogen selenide (H₂Se) gas or in a selenium vapor from a solid source. An ambient temperature is maintained between about 250° C. and 600° C.

The metals are typically deposited by electroplating, sputter deposition or printing. The metal deposition step is often followed by a cold deposition of selenium prior to the substrate entering a selenization furnace. The selenium deposition thickness is in the range of approximately 1 μm to 2 μm. By creating a sacrificial selenium layer on top of the CIG layer, indium is prevented from diffusing out of the metal layer in the form of a volatile indium selenide during the ramping of the furnace temperature. The temperature ramp can be of long duration, especially for thick glass substrates; however, for thin flexible foils, rapid temperature ramps (e.g., 10° C./s) are possible and are significant in reducing the problem of indium depletion. This two-step process is more controllable and easier to implement in system equipment in comparison to the co-evaporation technique; however, the resulting efficiencies generally are lower than those obtained by co-evaporation by 2% to 4%. The lower efficiencies are due to non-ideal grain formation and to the segregation of gallium and indium during the selenization step. Typically, gallium diffuses toward the back electrode to form a CuGaSe compound, while indium diffuses toward the barrier layer to form an indium rich compound near the front surface of the cell. Sulfur is sometimes added to the selenium in the furnace to compensate for this diffusion problem by increasing the bandgap of the material at the surface; however, the resulting absorbing layer is not a true CuInGaSe₂ compound and the known advantages of adding gallium to CIS are moderated.

A hybrid technique has been used to implement a co-sputtering/selenization; however, selenium poisoning of the sputtering targets can occur and the hot substrate results in poor selenium utilization. Thus this technique is generally more difficult to control than the co-evaporation process.

### SUMMARY

In one aspect, the invention features a method of depositing a copper indium gallium diselenide film on a substrate in which a layer of indium is deposited on a substrate and a layer of copper gallium is deposited on the layer of indium. The layers of copper and indium are selenized, and the steps of depositing a layer of indium, a layer of copper gallium and selenizing are repeated a plurality of times.

In another aspect, the invention features a method of depositing a copper indium gallium diselenide film on a substrate in which a first layer of indium is deposited on a substrate and a first layer of copper gallium is deposited on the first layer of indium. The first layers of indium and copper gallium are selenized. A second layer of indium is deposited on the selenized first layers of indium and copper gallium and a second layer of copper gallium is deposited on the second layer of indium. The second layer of indium has an increased indium content relative to the first layer of indium and the second layer of copper gallium has a decreased gallium content relative to the first layer of copper gallium. The second layers of indium and copper gallium are selenized.

In yet another aspect, the invention features a method of depositing a copper indium gallium diselenide film on a substrate. A first layer of copper gallium is deposited on a substrate and a first layer of indium is deposited on the first layer of copper gallium. A second layer of indium is deposited on the first layer of indium and a second layer of copper gallium is deposited on the second layer of indium. The first and second layers of indium and copper gallium are selenized.

### BRIEF DESCRIPTION OF THE DRAWINGS

The above and further advantages of this invention may be better understood by referring to the following description in conjunction with the accompanying drawings, in which like numerals indicate like structural elements and features in the various figures. For clarity, not every element may be labeled in every figure. The drawings are not necessarily to scale, emphasis instead being placed upon illustrating the principles of the invention.

FIG. 1 is an illustration of an embodiment of an apparatus for depositing a copper indium gallium diselenide film on a web according to the invention.

FIG. 2 is a flowchart representation of an embodiment of a method of depositing a copper indium gallium diselenide film on a web according to the invention.

FIG. 3 illustrates a selenization furnace for the apparatus of FIG. 1 that includes three independently controlled heating zones according to an embodiment of the invention.

FIG. 4A is a schematic illustration of a selenium trap for the apparatus of FIG. 1 according to an embodiment of the invention.

FIG. 4B is a cross-sectional side view illustration of pair of selenium traps and a selenization oven according to an embodiment of the invention.

FIG. 4C is a top view of an inner module of one of the selenium traps of FIG. 4B.

FIG. 4D is an end view of one of the selenium traps of FIG. 4B.

FIG. 5 is a block diagram of an embodiment of a system for deposition of a thin film on a substrate according to the invention.

FIG. 6A and FIG. 6B are a perspective view and a top view, respectively, of an embodiment of a system for deposition of a thin film on a substrate according to the invention.

FIG. 7 is a flowchart representation of an embodiment of a method of depositing a thin film on a substrate according to the invention.

FIG. 8 is a block diagram of another embodiment of a system for deposition of a thin film on a substrate according to the invention.

FIG. 9 is a flowchart representation of an embodiment of a method of depositing a copper indium gallium diselenide film on a substrate according to the invention.

FIG. 10 is an illustration of the structure of a CIGS film during processing according to the method of FIG. 9.

FIG. 11 is a flowchart representation of another embodiment of a method of depositing a copper indium gallium diselenide film on a substrate according to the invention.

FIG. 12 is an illustration of the structure of a CIGS film during processing according to the method of FIG. 11.

### DETAILED DESCRIPTION

The systems and methods of the present invention may include any of the described embodiments or combinations of the described embodiments in an operable manner. In brief overview, the systems and methods of the invention enable the deposition of a CIGS thin film by sputtering deposition on metal and plastic thin foils and discrete substrates. As used herein, a discrete substrate means an individual component such as a glass plate, a glass panel or a wafer. The flexibility and bandgap engineering advantages of co-evaporation techniques are realized without the production scaling problems of prior art co-evaporation systems. CIGS devices having high conversion efficiencies are manufactured using a multistep process that includes sputtering and selenization sequences. First, a substantially thin metal layer of CuInGa (e.g., approximately 0.15 μm thickness) is deposited onto a cold web substrate or a discrete substrate. For example, the substrate temperature in the sputtering region is preferably as low as practical (e.g., ambient temperature) but may be up to 300° C. due to operation of the sputtering equipment. Subsequently, selenization occurs in a selenization furnace which is in-line with the sputtering system. The process is repeated a number of times until a desired thickness of the absorber layer is attained (e.g., approximately 2.5 μm). The composition of each incremental thin metal layer can be varied throughout the full deposition process to achieve desired bandgap gradients and other film properties. Segregation of gallium and indium is substantially reduced or eliminated because each incremental layer is selenized before the next incremental layer is deposited. This epitaxial growth process (or layer-by-layer method) by a co-sputtering/selenization process eliminates the problems associated with the presence of selenium in the sputtering chamber. The process can be implemented in a roll-to-roll production system to deposit CIGS films on metal and plastic foils. Alternatively, the process can be implemented in a discrete substrate production system to deposit CIGS films on discrete substrates such as glass substrates and wafers.

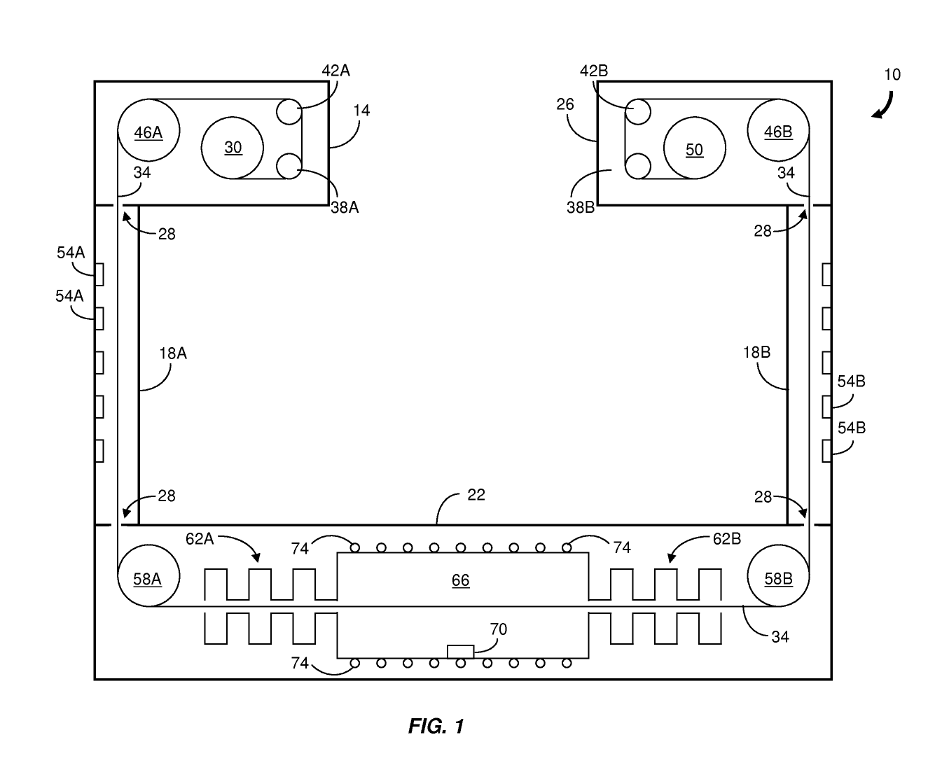

Referring to FIG. 1, an embodiment of an apparatus 10 for deposition of a copper indium gallium diselenide film on a web includes a payout zone 14, a first sputtering zone 18A, a selenization zone 22, a second sputtering zone 18B and a take-up zone 26. As used herein, the term zone means one or more chambers that can be operated to perform a specific process. The sputtering zones 18 and selenization zone 22 are coupled to respective pump systems (not shown) so that the vacuum level for the zones can be independently controlled. Low conductance slits 28 between the zones achieves a high degree of vacuum isolation between neighboring zones.

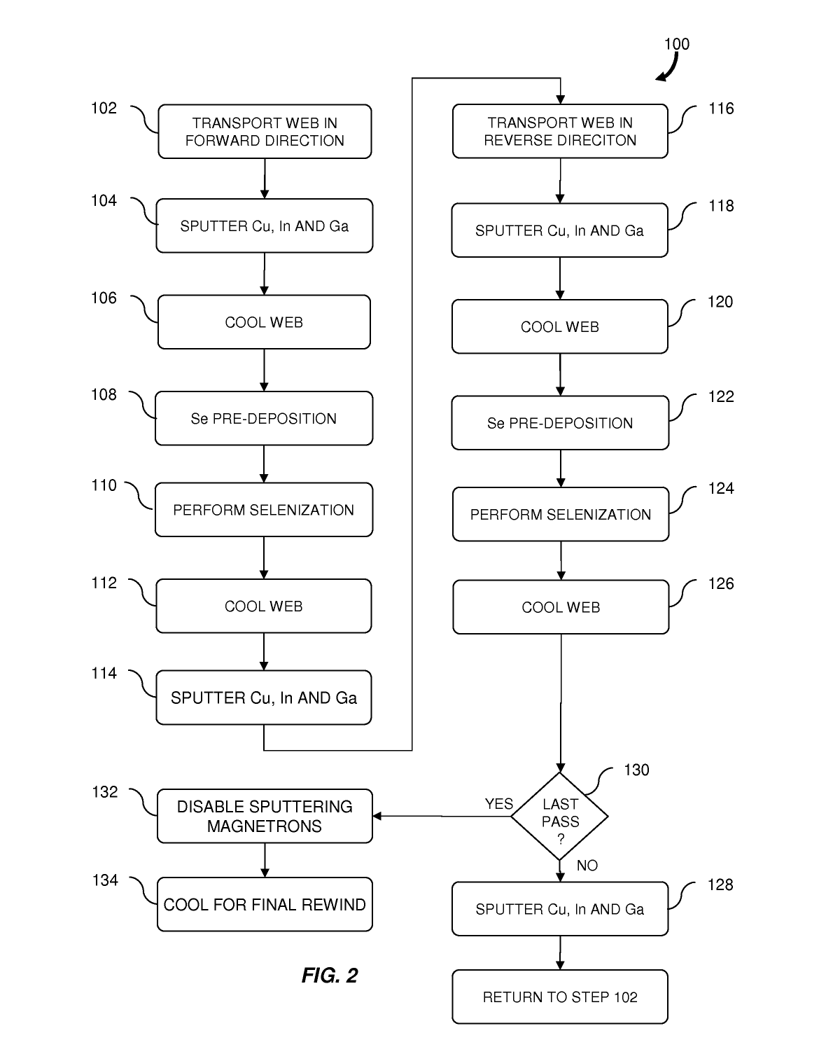

The payout zone 14 includes a payout roll 30 of web material 34, such as a thin plastic or metal foil, that is dispensed and transported through the other zones. The payout zone 14 also includes an idler roll 38A, a load cell 42 to maintain web tension and a cooling roll 46A that has a substantially larger diameter than the other rolls. The take-up zone 26 includes a take-up roll 50 to receive the web 34 after passage through the other zones. The take-up zone also includes rolls 38B, 42B and 46B that function as counterparts to rolls in the payout zone 14. At least one of the payout roll 30 and the take-up roll 50 is coupled to a web transport mechanism as is known in the art that enables the web 34 to pass through the intervening zones. The operation of the payout roll 30 and the take-up roll 50 can be reversed, that is, the payout roll 30 can also perform as a take-up roll and the take-up roll 50 can perform as a payout roll when the web is transported in a reverse direction (right to left) as described below with respect to FIG. 2.

The first sputtering zone 18A is a chamber having a plurality of sputtering magnetrons 54. The magnetrons 54 can be planar magnetrons or rotating cylindrical magnetrons as are known in the art. Target material composition for each magnetron 54 can vary relative to the materials of the targets for the other magnetrons 54 to achieve a graded composition structure in the resulting film.

The selenization zone 22 includes two cooling rolls 58 that surround two differentially pumped selenium traps 62 and a selenization furnace 66 having a selenium source 70. A multiple zone resistive heater comprising heating components 74 enables the furnace temperature along the web path through the selenization furnace 66 to vary.

FIG. 2 shows a flowchart representation of an embodiment of a method 100 of depositing a copper indium gallium diselenide film on a web according to the invention. Referring to FIG. 1 and FIG. 2, the web 34 is transported (step 102) from the payout zone 14 into the first sputtering zone 18A where the pressure is maintained below 0.01 Torr. During passage through the sputtering zone 18A, a deposition (step 104) of an incremental layer of copper, indium and gallium occurs. The targets of each magnetron 54 can have a variety of compositions. For example, each target material can be copper, indium, or alloys of each as with gallium or aluminum. The thickness of the incremental layer deposited on the web 34 during passage through the sputtering zone 18A varies according to different process parameters such as the web transport speed. By way of example, the thickness of the deposited incremental layer can be between 100 Å and 2000 Å.

After the first incremental layer is deposited, the web 34 enters the selenization zone 22. The web 34 first passes over a cooling roll 58A to cool (step 106) the web 34 before it enters a multistage differentially pumped selenium trap 62A. The trap 62A prevents selenium that may escape from the selenization furnace 66 from entering the sputtering zone 18A. The web 34 is pre-coated (step 108) with a thin layer (e.g., approximately 0.5 μm) of selenium in the trap 62A before entering the furnace 66. The relatively cold web temperature (e.g., less than 150° C.) allows selenium to condense on the web 34 as it moves through the trap 62. The web 34 then moves through the furnace 66 where selenization occurs (step 110) at a pressure that is substantially higher than the sputter pressure and at a temperature between 250° C. and 600° C. For example, the selenization can occur at a pressure in a range between 0.0001 Torr and 10 Torr. The pre-coating of selenium is advantageous in preventing indium depletion when the web temperature increases rapidly inside the furnace 66.

After exiting the furnace 66, the web 34 is cooled (step 112) to a lower temperature (e.g., less than 100° C.) by a second cooling roll 58B. The web 34 then passes through the second sputtering zone 18A where a second incremental layer of copper indium gallium of varying composition is deposited (step 114).

Once most of the web material from the payout roll 30 has been processed by transport in the forward direction, that is, dispensed from the payout roll 30 through the intervening zones and accumulated onto the payout roll 50, the deposition method 100 continues by transporting the web 34 in the reverse direction (step 116). While the web 34 moves back through the intervening zones, the original payout zone 14 functions as a take-up zone and the original take-up zone 26 functions as a payout zone. The web 34 passes through the sputtering and selenization zones 18 and 22 in reverse order to execute a sequence of steps (steps 118 to 128) that is reversed to the sequence of steps used during the forward transport. Thus a third incremental layer of copper indium gallium is deposited (step 118) on top of the second incremental layer in the second sputtering zone 18B before the second selenium pre-deposition occurs (step 122). Selenization is performed (step 124) during passage through the furnace 66 before a fourth incremental layer of copper indium gallium (step 128) is deposited onto the web 34.

Except for the first pass of the web 34 through the first sputtering zone 18A, it can be seen that selenization is performed after two consecutive passes of the web 34 through the same sputtering zone 18A or 18B. Thus two incremental layers are formed on the web 34 before selenization is performed. Advantageously, in some embodiments the power densities for the sputtering magnetrons can be reduced relative to the power densities for a single pass deposition of an incremental layer prior to selenization. In addition, because the power densities can be changed between passes, the composition of each layer can be changed without the need to change targets.

Forward and reverse transport processing are repeated a number of times until a CuInGaSe₂ film of a desired total thickness is deposited onto the web 34 (as determined at step 130). It should be noted that at the end of the process, the magnetrons in the sputtering zone 18A or 18B used after the last passage through the selenization furnace 66 are disabled (step 132) and the web 34 is cooled before a final rewind (step 134).

The iterative selenization implemented throughout the process reduces or eliminates the gallium and indium segregation problem that is common to two-step CIG processes because the first incremental layer and the pairs of consecutive incremental layers from round-trip passage through a sputtering zone 18 are selenized before the next pair of incremental layers is deposited. Moreover, because the layers to be selenized are thin, the time required for the web 34 to pass through the selenization furnace 66 can be short. Consequently, the web transport speed can be high. The multiple pass forward and reverse process and high web transport speed permit efficient construction of a multilayer structure having a varying composition and bandgap.

Although the apparatus 10 and method 100 described above relate primarily to a configuration having a single selenization furnace 66 and a pair of sputtering zones 18, it should be recognized that other configurations are contemplated according to principles of the invention. For example, multiple selenization furnaces and additional sputtering zones can be employed to enable multiple layers to be deposited and subsequently selenized while the web is transported in a single direction.

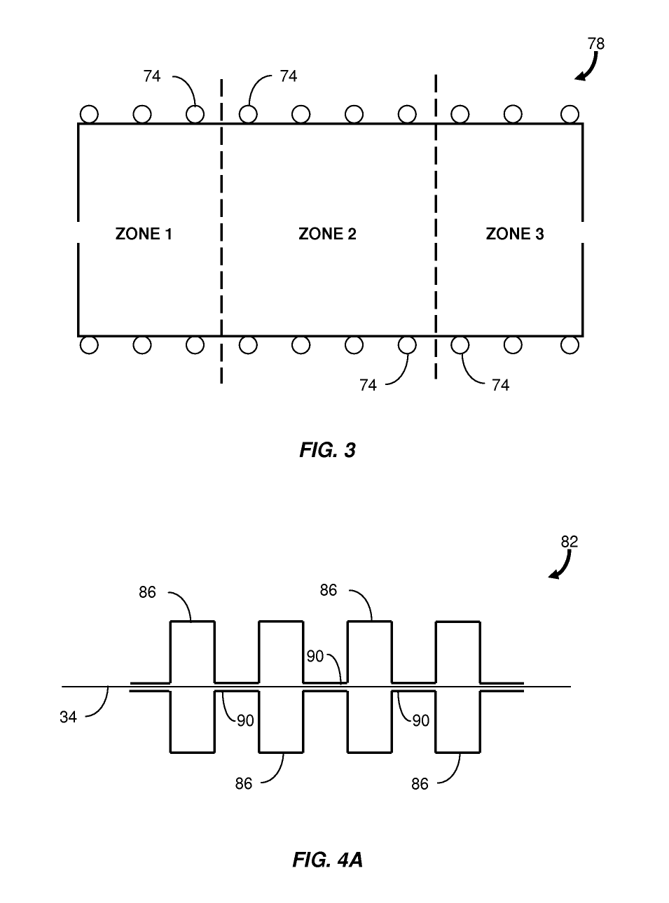

In some embodiments the selenization furnace 66 has multiple heating zones. FIG. 3 shows a selenization furnace 78 having three independently controlled heating zones. For example, ZONE 1 has a higher power density than ZONE 2 and ZONE 3 when the web 34 is transported from left to right in the figure. Conversely, ZONE 3 has a higher power density than the other zones when the web 34 moves in the opposite direction, that is, from right to left. By varying the temperature of the zones in this manner, a more rapid heating of the web 34 occurs as it enters the furnace 78. In some embodiments, the set temperature for the furnace 78 varies for each pass.

Various types of selenium traps can be used. For example, different schemes based on differential pumping to gradually transition from a higher pressure region to a lower pressure region as are known in the art can be used.

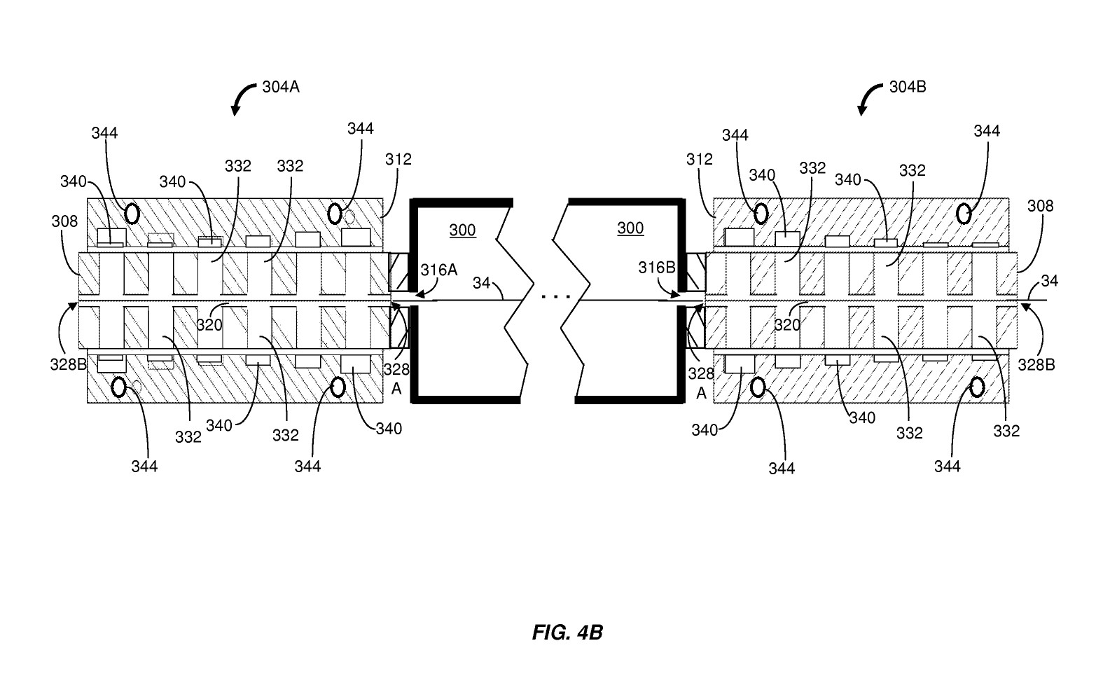

FIG. 4A is a schematic representation of an embodiment of a selenium trap 82 according to the invention. The trap 82 includes alternating plenums 86 and narrow gaps 90 of low conductance. The plenums 86 are maintained at a low temperature, for example, at a temperature between 0° C. and 20° C., while the gaps 90 are maintained at a substantially higher temperature, for example, 200° C. or greater. During operation, selenium does not accumulate on the hot surfaces of the gaps 90 but does accumulate on the cold surfaces of the plenums 86. In a preferred embodiment, the selenium pressure is reduced by a factor between approximately 5 and 10 for each gap 90 and neighboring plenum 86 with increasing distance from the selenization furnace 66. The numbers of gaps 90 and plenums 86 are preferentially determined by the desired pressure differential.

FIG. 4B is a cross-sectional side view illustration of a selenization oven 300 between a pair of selenium traps 304A and 304B according to an embodiment of the invention. Advantageously, each selenium trap 304 allows the consumption of selenium to be reduced by recapturing selenium and permitting the accumulated selenium to be recycled. In addition, the selenium remains localized and therefore does not contaminate other regions of the deposition system. Thus maintenance requirements are reduced.

The traps 304 enable various other system modules to operate under high vacuum conditions while maintaining a high selenium partial pressure in the oven 300. For example, the selenium partial pressure can be between 0.050 Torr and 10 Torr. In alternative applications, one or more selenium traps 304 can be used in systems in which various system modules operate near or at atmospheric pressure.

Each selenium trap 304 includes an inner module 308 and an outer module 312 that together function to recapture selenium that escapes through the oven apertures 316A and 316B. In a preferred embodiment, the inner module 308 is fabricated from graphite. Graphite is a suitable choice of material due to its relatively light weight and corrosive resistance. The inner module 308 includes a transport channel 320 to pass a web substrate 34 or discrete substrate. The transport channel 320 extends between a first trap aperture 328A at one end of the module 308 and a second trap aperture 328B at the opposite end of the module 308. Preferably the trap apertures 328 are shaped as slits. The trap apertures 328 and cross-section of the transport channel 320 are sized to pass the web substrate 34 (or discrete substrates) with sufficient clearance while limiting selenium vapor conductance from the selenization oven 300. By way of a numerical example, the slits can have a height of 5 mm and a width that is several millimeters greater than the width of the web substrate 34. A thin rectangular shape is also preferred for a discrete substrate system where the trap apertures 328 have a vertical dimension that is not substantially greater than the thickness of the discrete substrates.

Reference is also made to FIG. 4C and FIG. 4D which show a top view of the inner module 308 and an end view of the selenium trap 304, respectively. A number of plenums 332 extend from the transport channel 320 to an outer surface 336 of the inner module 308. The outer module 312 includes three body sections 312A, 312B and 312C bolted together or otherwise secured to each other. Similarly, the inner module includes two body sections 308A and 308B. The body of the outer module 312 substantially surrounds the body of the inner module 308 while leaving the ends with the entrance and exit apertures 328 accessible. Preferably, the gap between the inner module 308 and outer module 312 is small (e.g., less than 0.25 in.). In a preferred embodiment, the body sections of the outer module 312 are nickel-plated aluminum and the two sections of the inner module 308 are secured together using a stainless steel plate.

The outer module 312 includes a number of collection surfaces, preferably in the form of recessed regions or “pockets” 340 (FIG. 4B), that effectively terminate the plenums 332 across the gap and opposite the outer surface 336 of the inner module 308. Preferably, the depths of the pockets 340 decrease with increasing distance from the selenization oven 300 to accommodate the decreasing vapor condensation in each plenum 332. By way of a specific numerical example, in one embodiment the depth of the pocket 340 closest to the selenization oven is 0.25 in.

In some embodiments, the inner module 308 includes one or more heaters, such as an electrical cartridge heater, to ensure that the inner module 308 remains above the condensation temperature of the selenium vapor (approximately 200° C.). In other embodiments, heat conducted due to a direct coupling of the inner module 308 to the selenization oven 300 (e.g., by attachment) is sufficient to maintain the inner module temperature above the selenium condensation temperature. The outer module 312 is maintained at a temperature substantially below the selenization condensation temperature by a cooling system. In the illustrated embodiment, the cooling system includes coolant channels 344 that are arranged vertically and horizontally and that receive a coolant, such as water, from a coolant pump or other coolant source.

The inner and outer modules 308, 312 can be fabricated as compact units that enable the selenium traps 304 to be easily mounted along the transport path of the substrate at both sides of the selenization oven 300. By way of a numerical example, the length of the traps 304 can be between 10 cm and 30 cm and the width of the traps 304 is determined primarily according to the width of the substrate.

During operation of the illustrated embodiment as shown in FIG. 4B, the selenization oven 300 is maintained at a temperature typically in excess of 400° C. with a selenium partial pressure in excess of 0.050 Torr. The web substrate 34 (or discrete substrate) passes through the transport channel 320 of the first selenium trap 304A, through the selenization oven 300 and then through the transport channel 320 of the second selenium trap 304B. Selenium vapor that escapes from the oven 300 into a trap 304 does not condense onto surfaces of the inner module 308 which are at temperatures well above the selenium condensation temperature. Instead, the selenium vapor passes into the plenums 332 and selenium condenses on the relatively cold surfaces of the pockets 340 of the outer module 312.

The cold pocket surfaces allow efficient operation of the selenium pump 304. The arrangement of plenums 332 and pockets 340 act as a multi-stage differential pumping apparatus. For example, the selenium pressure is reduced by approximately a factor of ten for each stage progressing away from the selenization oven 300.

The trap 304 is configured to allow selenium that accumulates during system operation to be reclaimed. As described above, the density of the vapor in the plenums 332 decreases as the distance to the selenization oven 300 decreases, therefore the depth of a pocket 340 is preferably selected to accommodate the corresponding selenium accumulation rate for that pocket 340. Maintenance personnel can open the outer module 312, for example, by unbolting the body sections 312A, 312B and 312C to obtain access to the pockets 340 and to permit reclamation of the selenium deposits. After removal of the selenium, the body components of the outer module 312 are secured together about the inner module 308 so that the trap 304 can be reused. The reclaimed selenium can be reused in subsequent system operations.

It will be appreciated that the selenium trap can be adapted for a variety of other systems and applications, and that various changes to the structural features are contemplated. For example, in other embodiments the trap is a vapor trap used to restrict the location of other types of vapors for a variety of purposes, such as preventing contamination of surfaces or system components located away from a region of high vapor concentration and reclamation of other types of deposits from vapor condensation in the trap. Various features of the vapor trap, such as the number of plenums and the shapes and cross-sectional areas of the plenums and transport channel, can vary according to a particular application without departing from the principles of the invention. Moreover, the temperatures of the inner and outer modules for trapping various types of vapors are generally determined according to the condensation temperatures of the vapors.

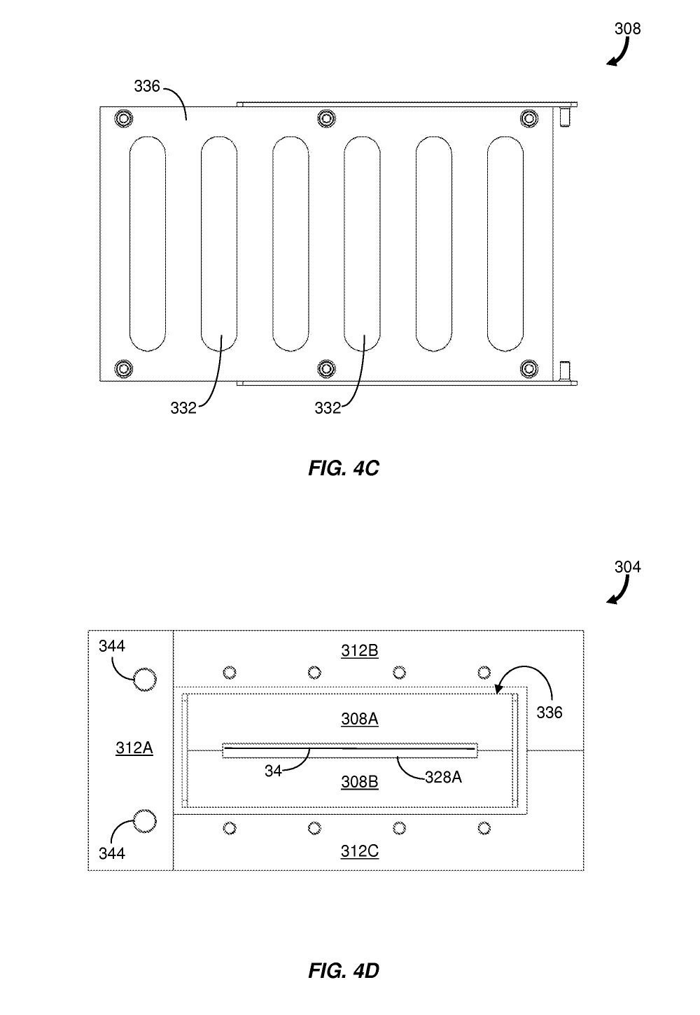

FIG. 5 is a functional block diagram of an embodiment of a system 150 for deposition of a thin film on a substrate. By way of example, the system 150 can be used to deposit a copper indium gallium diselenide film on a discrete substrate. The system 150 includes a metal deposition zone 152, a selenization zone 154 and a return cooling chamber 156. The system 150 also includes a substrate transport system (not shown) that transports a number of discrete substrates along a closed path 158 that passes through the zones 152, 154 and the return cooling chamber 156. The metal deposition zone 152 is configured to deposit a layer of a composite metal onto the discrete substrates as they pass through the zone. As used herein, a closed path means a path which has no beginning and no end. For example, a closed path can be a rectangular path or circular path along which the substrates are transported.

The metal deposition zone 152 can be a sputtering zone as is known in the art. The selenization zone 154 receives the discrete substrates after they pass through the metal deposition zone 152. Except for the final pass through the system 150, the return cooling chamber 156 receives the discrete substrates after they exit the selenization zone 154. The return cooling chamber 156 cools the discrete substrates before the substrates arrive at the metal deposition zone 152 for deposition of the next incremental layer.

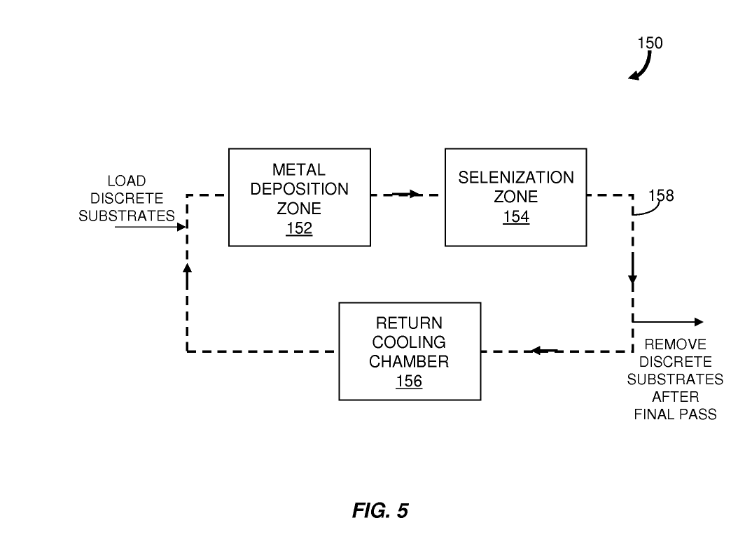

FIG. 6A and FIG. 6B are a perspective view and a top view, respectively, of an embodiment of a system 160 for deposition of a thin film on a substrate. The system 160 includes the system components shown in the functional block diagram of FIG. 5 in the form of a sputtering chamber 162, a selenization furnace 164 and selenium traps 172A and 172B, and a cooling chamber 166. For convenience, a portion of the top and side of the cooling chamber 166 are removed from FIG. 6A and FIG. 6B so that the substrate transport system 180 inside the cooling chamber 166 is visible. In various embodiments, the substrate transport system 180 includes one or more belt or roller type conveyance mechanisms to move the discrete substrates along the closed loop path 158.

The deposition system 160 also includes two load locks 168 and 174, and buffer stations 170A and 170B. In the illustrated embodiment, a load mechanism 176 (e.g., a robotic load station) retrieves discrete substrates from a supply of discrete substrates and places them onto a substrate transport system. Once the final pass through the sputtering chamber 162 and selenization furnace 164 is completed, an unload mechanism 178 (e.g., a robotic unload station) removes the discrete substrates from the substrate transport system 180 after the discrete substrates emerge from the exit load lock 174.

The sputtering chamber 162 includes a plurality of sputtering magnetrons 54, such as planar magnetrons or rotating cylindrical magnetrons. In some embodiments in which a copper indium gallium diselenide film is deposited, the targets are composed of copper, indium, or alloys of each with gallium or aluminum. In various embodiments, the target material composition for each magnetron 54 varies with respect to the target material composition for the other magnetrons 54 so that a graded composition structure is achieved in the deposited film.

In various embodiments, the selenization furnace 164 operates in a temperature range of about 250° C. to 600° C. Optionally, the selenization furnace 164 can include a multiple zone resistive heater so that the temperature along the closed path 158 within the furnace varies. The two selenium traps 172 on each side of the selenization furnace 164 preferably are differentially pumped multistage traps. The selenium traps 172 prevent selenium that may escape the furnace 164 from entering the sputtering chamber 162 or adversely affecting other system components.

The sputtering chamber 162 and selenization furnace 164 are coupled to separate pump systems (not shown) to permit the vacuum levels for each of these zones to be independently controlled. Low conductance apertures, or substrate passages, at locations between system components and selenium traps 172 results in a high degree of vacuum isolation and enables more efficient vacuum control.

The cooling chamber 166 operates at atmospheric pressure is configured to reduce the temperature of the discrete substrates prior to a subsequent pass through the sputtering chamber 162 and selenization furnace 164. Various forms of coolers may be employed. In one embodiment, a cold plate extending at least along a portion of the length of the cooling chamber 166 is mounted above the substrate path such that discrete substrates passing underneath are cooled by atmospheric conduction.

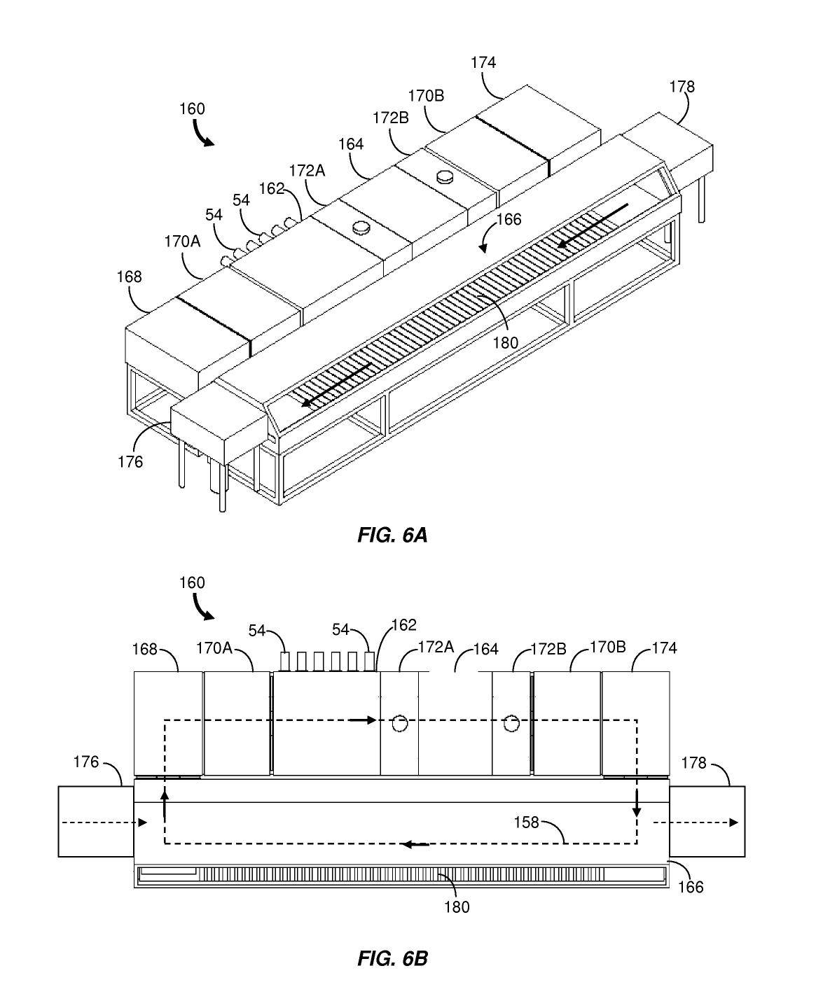

FIG. 7 is a flowchart representation of an embodiment of a method 200 of depositing a thin film, for example, a copper indium gallium diselenide film, on a substrate according to the invention. Referring to FIGS. 6A, 6B and 7, discrete substrates are loaded (step 202) on or into the substrate transport system 180 which transports the substrates into the load lock 168. After the substrate environment is reduced to the appropriate vacuum level, the discrete substrates exit the load lock 168, pass through the first buffer station 170A and pass (step 204) through the sputtering chamber 162 where a layer of composite metal is deposited. The discrete substrates continue along the closed path and are transported (step 206) through the first selenium trap 172A, the selenization furnace 164 and the second selenium trap 172B. Subsequently, the discrete substrates pass through the second buffer station 170B before entering the exit load lock 174 where the substrate environment is returned to atmospheric pressure. If it is determined (step 208) that further incremental deposition layers are to be deposited, the discrete substrates that leave the exit load lock 174 are transported (step 210) through the cooling chamber 166 before subsequent deposition and selenization occur (steps 204 and 206). If it is determined (step 208) that the last incremental layer has been deposited, the discrete substrates exit the exit load lock 174 and are unloaded (step 212) or removed from the substrate transport system 180. The number of passes that the discrete substrates make along the closed path can be based on a variety of parameters, for example, the desired structure and thickness of the deposited films and the transport speed.

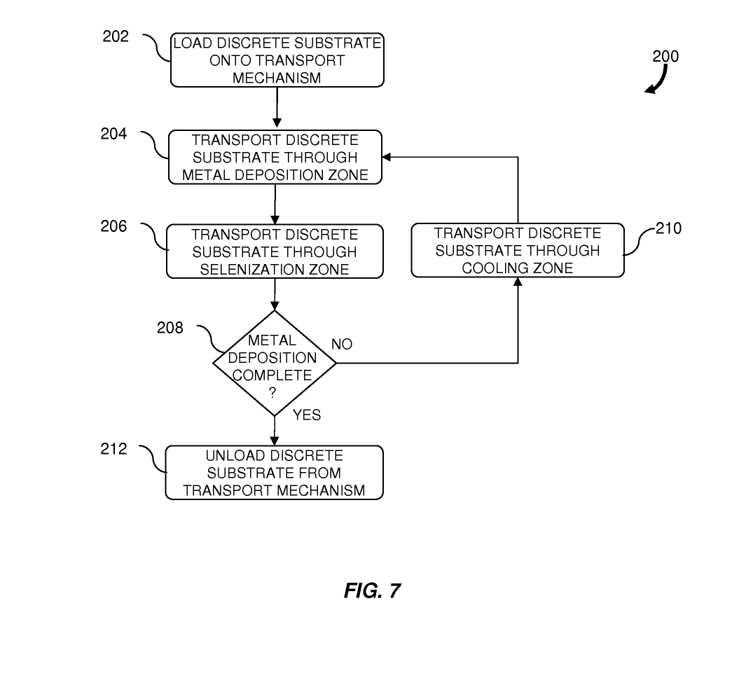

Although the embodiments of a system for discrete substrates described above relate to transporting the discrete substrates along a closed path, in alternative embodiments the system transports discrete substrates along an open path, that is, a path that includes two ends: a load end and an unload end. FIG. 8 is a functional block diagram of an embodiment of one such system 182 where each discrete substrate passes through a group of system components that includes a metal deposition zone 152, a selenization zone 154 and a cooling chamber 156. Unlike the system 150 of FIG. 5, each additional incremental layer is deposited by a single pass through a subsequent group of system components that includes a metal deposition zone 152, selenization zone 54 and cooling chamber 156. By way of example, each group of system components can include a cooling chamber 166 and the various components between the load locks 168 and 174, inclusive, as illustrated in FIGS. 6A and 6B. Although the embodiment illustrated in FIG. 8 shows three groups of system components, any number of groups that is greater than or equal to two can be used. It should be understood that the number of incremental layers that can be deposited on the discrete substrate is equal to the number of groups of system components. In still other embodiments, a system can include a combination of one or more closed paths and one or more open paths with each path having at least one group of system components.

Various embodiments of methods for depositing a copper indium gallium diselenide film on a web or discrete substrate are described above. Variations on these methods are possible and can be used to achieve desired properties. For example, it may be desirable to generate a CIGS film that where the content of gallium and indium vary along the thickness of the film. In certain embodiments, such a film increases in gallium content with decreasing distance to the substrate and increases in indium content with increasing distance from the substrate.

Conventional processes for creating a CIGS film with a gallium and indium gradient include first depositing copper, indium and gallium by a technique such as vacuum evaporation, sputtering, electroplating or inkjet printing and then performing a selenization step. The deposition step is performed in a manner to achieve the desired gallium and indium gradients; however, during the subsequent selenization, indium in contact with the selenium at temperatures of approximately 200° C. to 400° C. results in formation of indium selenide, a volatile compound that depletes the indium in the CIGS layer. In an alternative known procedure, a thin layer (e.g., 2 μm) of selenide is deposited onto the cold CIGS layer and then the substrate and deposited layers are subjected to a thermal process that rapidly increases the temperature to a value that is greater than the critical selenization temperature to achieve full selenization. This alternative procedure is difficult to control and may not completely prevent indium depletion.

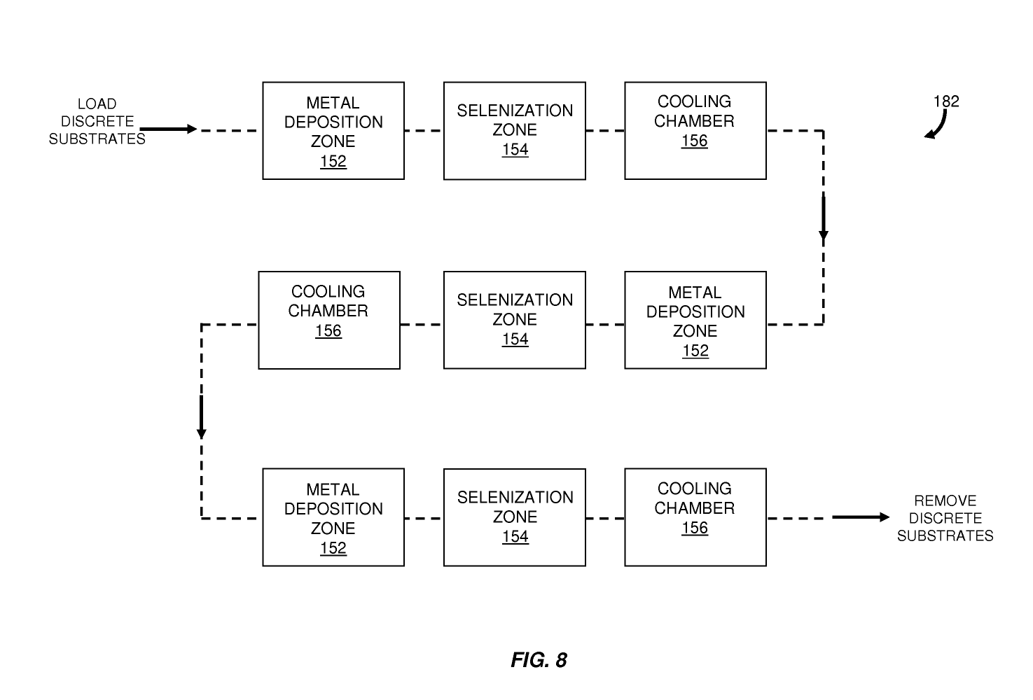

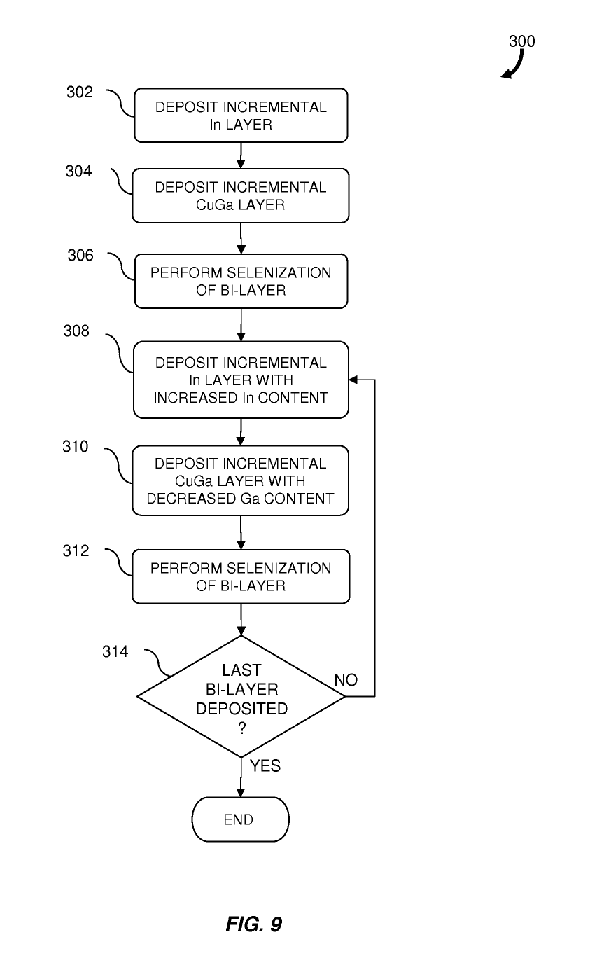

FIG. 9 is a flowchart representation of an embodiment of a method 300 of depositing a CIGS film on a substrate that reduces or eliminates the problem of indium depletion during selenization. FIG. 10 illustrates a CIGS film 250 formed of incremental bi-layers that are deposited and selenized when performing the method 300. It should be recognized that one or more layers of material, such as a molybdenum layer for a back electrical contact, may be formed on the substrate prior to initiation of the method 300. Initially, an incremental layer of indium 252A is deposited (step 302) followed by deposition (step 304) of an incremental layer of copper gallium 252B to create a first bi-layer 252 that is subsequently selenized (step 306). By “capping” the indium layer 252A with the copper gallium layer 252B, there is no direct contact of the indium with the selenium during the selenization process and therefore depletion of the indium through the creation of indium selenide is avoided. The next bi-layer 254 is formed first by depositing (step 308) an incremental indium layer 254A that has increased indium content relative to the preceding incremental indium layer 252A and then by depositing (step 310) a copper gallium layer 254B that has decreased gallium content relative to the preceding incremental copper gallium layer 252B. The second bi-layer 254 is then selenized (step 312). If another bi-layer is to be created (step 314), the method 300 returns to step 308 and continues through step 312 until the desired number of additional bi-layers (256, . . . , 258) are formed and selenized. In this manner, a full CIGS film 250 is formed with the desired gallium and indium content gradients. In preferred embodiments, the thickness of each incremental layer of indium or copper gallium is in a range of about 300 Å to about 1,500 Å. Although the embodiment of the method 300 includes increasing indium content and decreasing gallium content as each incremental indium layer and each incremental copper gallium layer is deposited, respectively, alternative embodiments can have opposite content gradients. Furthermore, the content gradients are not limited to constant values, that is, the indium content and gallium content along the thickness of the CIGS film 250 can vary in any desired manner.

The method 300 can be performed with a deposition system that can deposit the incremental layers of each bi-layer and then selenize each bi-layer. By way of examples, the method can be performed using the system 150 of FIG. 5, the system 160 of FIGS. 6A and 6B, or the system 182 of FIG. 8 to create the CIGS film on a discrete substrate. In another example, the apparatus 10 of FIG. 1 can be adapted using the method 300 to create the CIGS film on a web substrate.

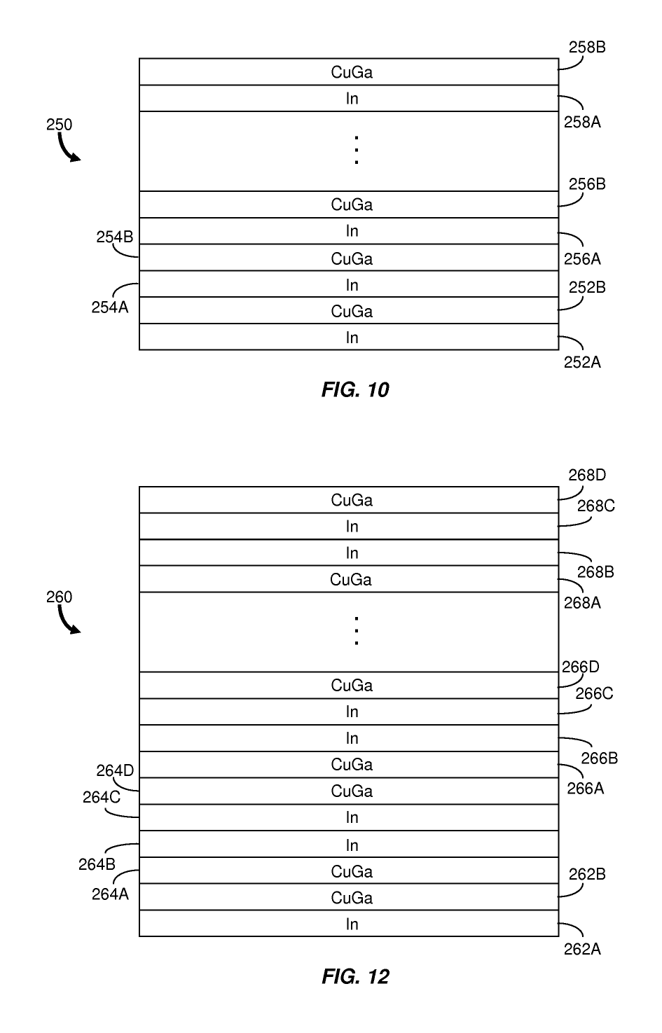

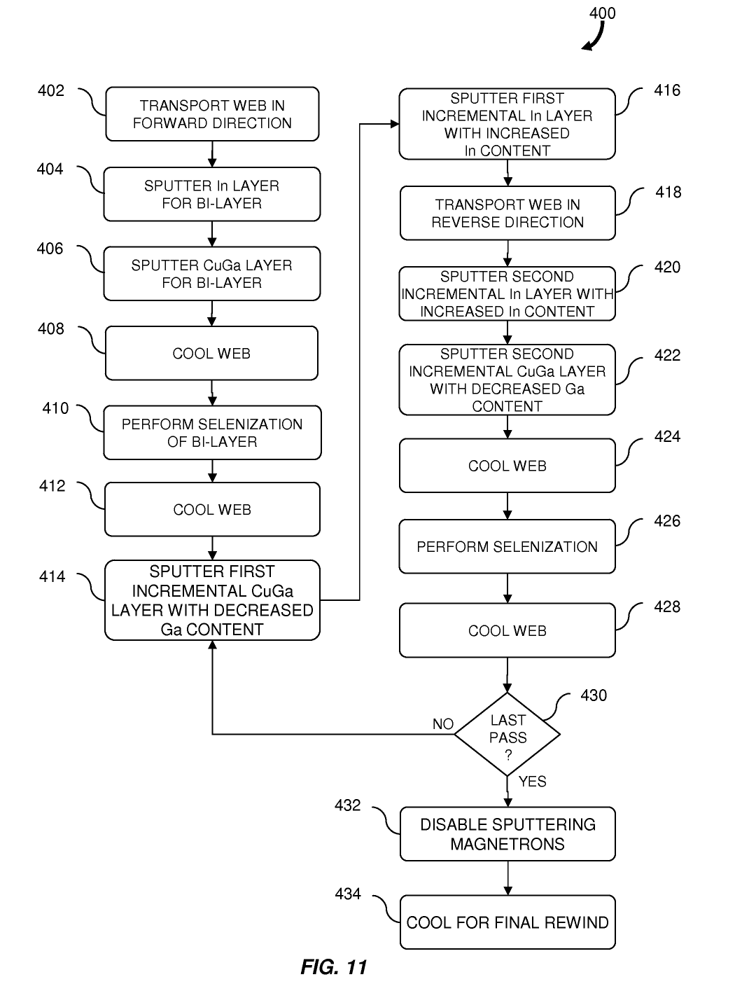

FIG. 11 is a flowchart representation of an alternative embodiment of a method 400 of depositing a CIGS film on a substrate and FIG. 12 is an illustration of the structure of a CIGS film 260 formed of incremental layers that are formed according to the method 400. The method 400 is effective for reducing or eliminating the depletion of indium during selenization processing. Reference is also made to the roll-to-roll deposition apparatus 10 shown in FIG. 1 although it will be recognized that other deposition systems capable of depositing the desired CIGS film structure 260 of incremental layers onto a web substrate or a discrete substrate, and performing the appropriate selenization of layers can be used.

According to the illustrated embodiment of the method 400, a web 34 is transported (step 402) in a forward direction. The web may include one or more layers of intervening material, such as a molybdenum layer, that are formed prior to initiation of the method 400. The web 34 passes through the first sputtering zone 18A where an incremental layer of indium 262A is deposited (step 404) followed by deposition (step 406) of an incremental layer of copper gallium 262B. The proper order of incremental layers is achieved by configuring the order of sputtering targets within the sputtering zone 18A. After exiting the first sputtering zone 18A, the web 34 is cooled (step 408) by cooling roll 58A before entering the selenization furnace 66 to selenize (step 410) the bi-layer 262. The incremental copper gallium layer 262B “caps” the incremental indium layer 262A, therefore there is no direct exposure of the incremental indium layer 262A with selenium during the selenization process.

The web 34 is cooled (step 412) after exiting the selenization furnace 66 and then enters the second sputtering zone 18B where a first incremental layer of copper gallium 264A is deposited (step 414) and then a first incremental layer of indium 264B is deposited (step 416). Preferably, the web 34 is cooled before wound on the take-up roll 50. The web 34 is then transported (step 418) in the reverse direction so that it passes again through the second sputtering zone 18B where a second incremental layer of indium 264C and then a second incremental layer of copper gallium 264D are deposited (steps 420 and 422, respectively). The quad-layer 264 includes incremental indium layers 264B and 264C that have increased indium content relative to the preceding incremental indium layer 262A. The quad-layer 264 includes incremental copper gallium layers 264A and 264D that have decreased gallium content relative to the preceding incremental copper gallium layer 262B. The desired order of the incremental layers within the quad-layer 264 is achieved by appropriate arrangement of sputtering targets within the second sputtering zone 18B. The last two incremental layers 264C and 264D can have different indium and gallium content than their counterparts in the first two incremental layers 264B and 264A, respectively, in order to continue the development of the desired gradients however, this is not a requirement. For example, gradients within the quad-layer 264 can be achieved by adjusting operating parameters and targets of the second sputtering zone 18B between the forward and reverse passes.

After exiting the second sputtering zone 18B in the reverse direction, the web 34 is cooled (step 424) by cooling roll 58A before entering the selenization furnace 66 to selenize (step 426) the quad-layer 264. The second incremental copper gallium layer 264D “caps” the incremental indium layers 264B and 264C, and reduces indium depletion during the selenization of the quad-layer 264. The web 34 is cooled (step 428) after exiting the selenization furnace 66. If the CIGS film is not complete (step 430), the method 400 returns through steps 414 to 428 to generate and selenize the next quad-layer 266 with modifications to the indium and gallium content of the respective incremental layers to achieve the desired compositional gradients. The method 400 continues until it is determined (step 430) that the complete CIGS film 260 comprised of bi-layer 262 and all quad-layers 264, 266, . . . , 268 with the desired indium and gallium content gradients is formed. Subsequently, the magnetrons 54 of the sputtering chambers 18 are disabled (step 432) and the web 34 is cooled (step 434) for a final rewind.

In the embodiments of the methods 300 and 400 described above, the incremental layers, bi-layers and quad-layers are sufficiently thin so that the local distribution of indium and gallium has a negligible affect on the macro distribution of indium and gallium in the CIGS film. Moreover, there is a diffusion of the incremental layers into adjacent layers after selenization such that the discrete nature of each incremental layer is less apparent. Advantageously, by using copper gallium as a cap layer for each bi-layer or quad-layer, the generation of indium selenide during selenization and the corresponding depletion of indium from the CIGS film are prevented. Moreover, the methods 300 and 400 enable the desired indium and gallium content gradients to be formed in the CIGS film.

While the invention has been shown and described with reference to specific embodiments, it should be understood by those skilled in the art that various changes in form and detail may be made therein without departing from the spirit and scope of the invention as recited in the accompanying claims. For example, in one such embodiment a thin layer of selenium is deposited onto each cap layer of copper gallium of the cooled substrate prior to the selenization of the bi-layer or quad-layer. The deposition of each selenium layer further improves the reduction in indium depletion during the selenization steps. In other variations, the number of incremental layers that are deposited and subsequently selenized is different from the bi-layer and quad-layer structures as long as the last deposited incremental layer is a cap layer of copper gallium.

What is claimed is:

1. A method of depositing a copper indium gallium diselenide film on a substrate, the method comprising:
(a) depositing a layer of indium on a substrate;
(b) depositing a layer of copper gallium on the layer of indium;
(c) selenizing the layers of indium and copper gallium; and
repeating a sequence of the steps (a) through (c) a plurality of times.

2. The method of claim 1 further comprising depositing at least one additional layer of indium or copper gallium prior to step (b) and wherein step (c) comprises selenizing the layer of indium, the layer of copper gallium and the at least one additional layer of indium or copper gallium.

3. The method of claim 1 wherein, for each repetition of step (a), an indium content of the layer of indium is modified relative to a last deposited layer of indium.

4. The method of claim 1 wherein, for reach repetition of step (b), a gallium content of the layer of copper gallium is modified relative to a last deposited layer of copper gallium.

5. The method of claim 1 wherein, for each repetition of step (a), an indium content of the layer of indium is increased relative to a last deposited layer of indium and wherein, for each repetition of step (b), a gallium content of the layer of copper gallium is decreased relative to a last deposited layer of copper gallium.

6. The method of claim 1 where step (c) comprises heating the substrate in a partial pressure selenium atmosphere.

7. The method of claim 6 wherein heating the substrate comprises heating the substrate to a temperature greater than 200° C.

8. The method of claim 1 wherein the depositing of the first and second layers of indium and copper gallium comprises one of an evaporation process, a sputtering process, an electroplating process and an inkjet printing process.

9. The method of claim 1 wherein a thickness of each layer of indium is in a range of 300 Å to 1,500 Å.

10. The method of claim 1 wherein a thickness of each layer of copper gallium is in a range of 300 Å to 1,500 Å.

11. The method of claim 1 wherein the substrate is a web substrate.

12. The method of claim 1 wherein the substrate is a discrete substrate.

13. The method of claim 1 further comprising depositing a layer of selenium on the layer of copper gallium and wherein step (c) comprises selenizing the layers of indium and copper gallium and step (d) comprises repeating a sequence of the steps (a) through (c) and the depositing of a layer of selenium a plurality of times.

14. A method of depositing a copper indium gallium diselenide film on a substrate, the method comprising:
depositing a first layer of indium on a substrate;
depositing a first layer of copper gallium on the first layer of indium;
selenizing the first layers of indium and copper gallium;
depositing a second layer of indium on the selenized first layers of indium and copper gallium, the second layer of indium having an increased indium content relative to the first layer of indium;
depositing a second layer of copper gallium on the second layer of indium, the second layer of copper gallium having a decreased gallium content relative to the first layer of copper gallium; and
selenizing the second layers of indium and copper gallium.

15. The method of claim 14 where the steps of selenizing comprise heating the substrate in a partial pressure selenium atmosphere.

16. The method of claim 15 wherein heating the substrate comprises heating the substrate to greater than 200° C.

17. The method of claim 14 wherein the depositing of the first and second layers of indium and the first and second layers of copper gallium comprises one of an evaporation process, a sputtering process, an electroplating process and an inkjet printing process.

18. A method of depositing a copper indium gallium diselenide film on a substrate, the method comprising:
depositing a first layer of copper gallium on a substrate;
depositing a first layer of indium on the first layer of copper gallium;
depositing a second layer of indium on the first layer of indium;
depositing a second layer of copper gallium on the second layer of indium; and
selenizing the first and second layers of indium and copper gallium.

19. The method of claim 18 wherein the depositing of the first and second layers of indium and the first and second layers of copper gallium comprises one of an evaporation process, a sputtering process, an electroplating process and an inkjet printing process.

20. The method of claim 18 wherein selenizing comprises heating the substrate in a partial pressure selenium atmosphere.

21. The method of claim 20 wherein heating the substrate comprises heating the substrate to greater than 200° C.

22. The method of claim 18 further comprising:
depositing a third layer of copper gallium on the substrate;
depositing a third layer of indium on the third layer of copper gallium;
depositing a fourth layer of indium on the third layer of indium;
depositing a fourth layer of copper gallium on the fourth layer of indium; and
selenizing the third and fourth layers of indium and copper gallium.

23. The method of claim 22 wherein an indium content of the third and fourth layers of indium is increased relative to the first and second layers of indium and wherein a gallium content of the third and fourth layers of copper gallium is decreased relative to the first and second layers of gallium.
